(19) United States
(12) Patent Application Publication
(10) Pub. No.: US 2025/0118890 A1
(43) Pub. Date: Apr. 10, 2025

(54) TRANSMISSION DEVICE AND PREPARATION METHOD THEREFOR, AND QUANTUM DEVICE INTEGRATION COMPONENT AND QUANTUM COMPUTER

(71) Applicant: Origin Quantum Computing Technology (HeFeI) Co., LTD., Hefei, Anhui (CN)

(72) Inventors: Hui ZHANG, Hefei, Anhui (CN); Hui YANG, Hefei, Anhui (CN); Ye LI, Hefei, Anhui (CN); Jianhao JIA, Hefei, Anhui (CN)

(21) Appl. No.: 18/416,027

(22) Filed: Jan. 18, 2024

Related U.S. Application Data
(63) Continuation of application No. PCT/CN2022/119526, filed on Sep. 19, 2022.

(30) Foreign Application Priority Data
Sep. 18, 2021 (CN) 202111113676.8

(51) Int. Cl. H01Q 1/38; G06N 10/40; H01Q 1/22; H01Q 1/36

(52) U.S. Cl. CPC H01Q 1/38; G06N 10/40; H01Q 1/2283; H01Q 1/364

(57) ABSTRACT

a transmission device and the fabricating method therefor, a quantum device integration component and a quantum computer, and belongs to the field of quantum information. The transmission device includes: a substrate; a micro-strip line layer formed on the substrate; a dielectric layer formed on the micro-strip line layer; and a ground layer and a port pad formed on the dielectric layer, wherein the ground layer is electrically connected to a ground plate of the micro-strip line layer, and the port pad is electrically connected to a conductor strip of the micro-strip line layer. The transmission device can be fabricated based on the existing integrated circuit fabricating process. In this transmission device, the micro-strip line layer can have a multi-layer stacking arrangement, so that high-density wiring on the substrate with a limited area can be achieved to adapt to the packaging needs of large-scale quantum chips.

### CROSS-REFERENCE TO RELATED PATENT APPLICATION

The present application claims is a Continuation of and claims priority to PCT/CN2022/119526 filed Sep. 19, 2022 and priority to Chinese patent application No. CN 202111113676.8 filed on Sep. 19, 2021 and entitled “Transmission device and fabricating method therefor, quantum device integration component, and quantum computer”, which is incorporated herein by reference in its entirety.

### TECHNICAL FIELD

The present application belongs to the field of quantum information, in particular to the field of quantum computing, and specifically, the present application relates to a transmission device and the fabricating method therefor, a quantum device integration component, and a quantum computer.

### BACKGROUND

A quantum chip is a core part of the quantum computers. In order to ensure a stable operation and a signal transmission of a quantum chip, it is necessary to package the quantum chip and lead out a signal transmission port to a controlling and reading apparatus of the quantum chip through a packaging component.

Currently, a traditional PCB substrate is commonly used to lead out the signal transmission port of the quantum chip through a transmission route on the PCB substrate. However, as the number of qubits increases, the wiring on the quantum chip becomes increasingly dense, and the volume of the PCB substrate further needs to increase, thereby causing the quantum chip packaging component to occupy more and more space in the refrigerator, affecting the use of quantum chip.

### SUMMARY

The object of the embodiments of the present application is to provide a transmission device and a fabricating method therefor, a quantum device integration component and a quantum computer to solve the shortcomings in the prior art.

An embodiment of the present application provides a transmission device, which includes:
a substrate;
a micro-strip line layer, formed on the substrate;
a dielectric layer, formed on the micro-strip line layer; and
a ground layer and a port pad, formed on the dielectric layer, wherein the ground layer is electrically connected to a ground plate of the micro-strip line layer, and the port pad is electrically connected to a conductor strip of the micro-strip line layer.

Another embodiment of the present application provides a quantum device integration component, which includes:
a quantum chip, on which a superconducting circuit is formed; and
the transmission device mentioned above, wherein the quantum chip is mounted on the transmission device via Flip Chip or Wire Bond, the ground layer and the quantum chip are common-grounded, and the conductor strip is coupled to the superconducting circuit.

In some embodiments, a through-hole is formed on the quantum chip, a superconducting interconnector is formed in the through-hole, and the superconducting interconnector and the port pad are connected in contact.

Yet another embodiment of the present application provides a quantum computer, which is at least provided with the above transmission device, or the above quantum device integration component.

Yet another embodiment of the present application provides a method for fabricating a transmission device, which includes:
providing a substrate;
forming a micro-strip line layer on the substrate;
forming a dielectric layer on the micro-strip line layer; and
forming a ground layer and a port pad on the dielectric layer, wherein the ground layer is electrically connected to a ground plate of the micro-strip line layer, and the port pad is electrically connected to a conductor strip of the micro-strip line layer.

Through one embodiment, high-density wiring on a limited-area substrate can be achieved, thereby adapting to the packaging needs of large-scale quantum chips.

### BRIEF DESCRIPTION OF THE DRAWINGS

FIG. 1 is a schematic diagram of a structure of a quantum device integration component provided by an embodiment of the present application.

FIG. 2 is a schematic diagram of a structure of a transmission device provided by an embodiment of the present application.

FIG. 3 is a schematic plane view of a transmission device provided by an embodiment of the present application.

FIG. 4 is a cross-sectional view of AA section in FIG. 3.

### REFERENCE SIGNS

1—quantum chip, 2—transmission device, 3—superconducting interconnector,
21—substrate, 22—micro—strip line layer, 23—dielectric layer, 24—ground layer, 25—second port, 26—first port,
221—first ground plate, 222—first dielectric layer, 223—conductor layer, 224—second dielectric layer, 225—second ground plate,
2231—conductor strip, 271—first superconducting element, 272—second superconducting element, 273—second electrical element, 274—first electrical element.

### DETAILED DESCRIPTION

The following detailed description is illustrative only and is not intended to limit embodiments and/or application or usage of the embodiments. Furthermore, there is no intention to be bound by any express or implied information presented in the sections of preceding “Background”, or “Summary”, or the section of “Detailed Description”.

In order to make the objective, technical solutions and advantages of the present application clearer and more understandable, one or more embodiments will be described with reference to the accompanying drawings, wherein similar reference signs are used to refer to similar components throughout. In the following description, for the purpose of explanation, numerous specific details are set forth in order to provide a thorough understanding of the one or more embodiments. However, obviously, in various cases, the one or more embodiments may be practiced without these specific details and the each of the embodiments may be combined and referenced with each other without conflicts.

It should be noted that, the terms such as “first” and “second” and the like in the description and claims as well as the accompanying drawings are used to distinguish similar objects, and not used to describe a specific order and sequence. It should be understood that the data used in this way can be interchanged in appropriate circumstances, so that the embodiments described herein can be implemented in order other than those illustrated or described herein. Moreover, the terms “comprise”, “have” or any other variations thereof are intended to encompass a non-exclusive inclusion, such as a process, method, system, product or equipment that includes a series of steps or units does not need to be limited to those clearly listed steps or units, but may include other steps or units that are not clearly listed or inherent in the process, method, product or equipment.

Furthermore, it should be understood that when a layer (or film), region, pattern or structure is referred to as being “on” a substrate, layer (or film), region and/or pattern, it can be directly on another layer or substrate, and/or an insertion layer may also be present. Furthermore, it will be understood that when a layer is referred to as being “under” another layer, it can be directly under another layer, and/or one or more insertion layers may also be present. Furthermore, “on” and “under” each of the layers may be referred based on the accompanying drawings.

According to different physical systems used to construct qubits, physical implementation methods for the qubits include superconducting quantum circuits, semiconductor quantum dots, ion traps, diamond vacancies, topological quantum, photons, etc.

Superconducting quantum computing is currently the fastest and best implementation method for solid state quantum computing. Since an energy level structure of a superconducting quantum circuit can be controlled by an external electromagnetic signal, the design and customization of the circuit are highly controllable. Meanwhile, thanks to the existing mature integrated circuit process, a quantum chip based on the superconducting quantum circuit has scalability that is incomparable to most quantum physics systems. Qubits located on the quantum chip often use capacitors and nonlinear inductors (for example, Josephson knot) to be constructed.

For example, a common quantum chip fabricating process includes a substrate; a superconducting layer formed on the substrate; patterning the superconducting layer to obtain ground, a capacitive plate to ground, a magnetic flux signal line, a pulse signal line, a reading resonant cavity, a reading signal line, and a fabrication area of the superconducting quantum interference device squid, wherein the fabrication area is located between the ground and the capacitive plate, and the reading resonant cavity and the reading signal line are coupled; forming a superconducting quantum interference device squid in the fabrication area, wherein the formed superconducting quantum interference device squid is coupled with the magnetic flux signal line and the pulse signal line, and is coupled with the reading resonant cavity through the capacitive plate. When the quantum chip is run, the qubit is controlled and read by using the magnetic flux signal line, the pulse signal line, the reading resonant cavity, and the reading signal line.

Usually, a magnetic flux quantum signal line, a pulse adjusting signal line and the reading signal line have corresponding ports on the quantum chip (which are commonly referred to as signal transmission ports). When packaging the quantum chip, a PCB substrate is used to lead out the signal transmission port of the quantum chip through a transmission route on the PCB substrate. However, as the number of qubits increases, the wiring on the quantum chip becomes more and more dense, and the volume of the PCB substrate also needs to increase accordingly, which causes the space of the quantum chip package component occupied in the refrigerator to become larger and larger, affecting the use of quantum chips.

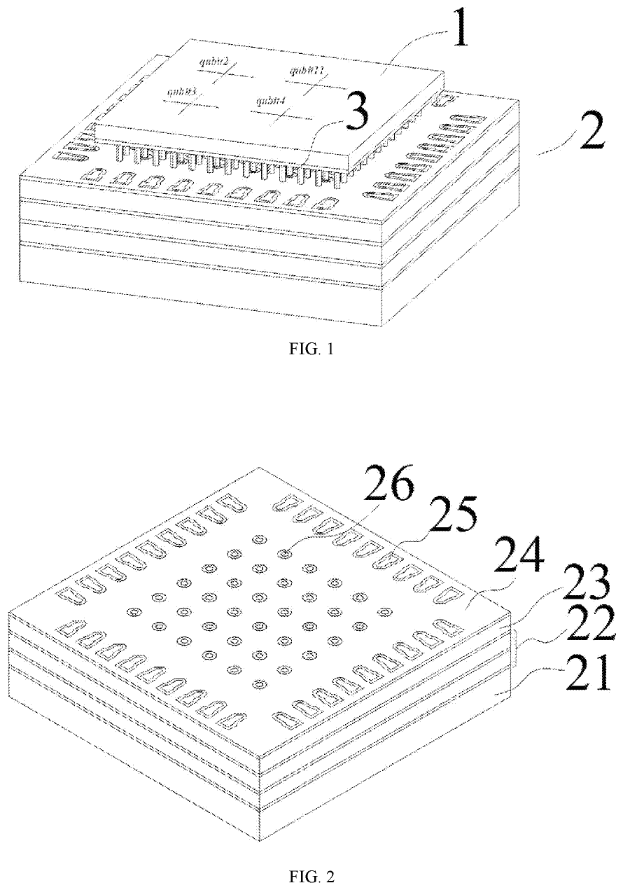

FIG. 1 is a schematic diagram of a structure of a quantum device integration component provided by an embodiment of the present application.

FIG. 2 is a schematic diagram of a structure of a transmission device provided by an embodiment of the present application.

FIG. 3 is a schematic plane view of a transmission device provided by an embodiment of the present application.

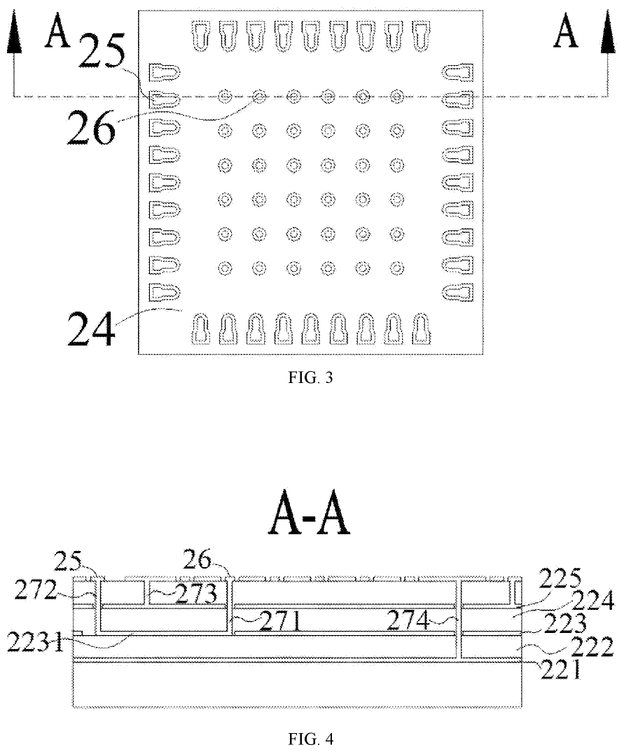

FIG. 4 is a cross-sectional view of AA section in FIG. 3.

Referring to FIG. 1, FIG. 2 and FIG. 3, the present application provides a transmission device and a fabricating method therefore, a quantum device integration component and a quantum computer to solve the shortcomings in the prior art. The quantum device integration component provided by the embodiment of the present application includes: a quantum chip 1, on which a superconducting circuit is formed, the superconducting circuit including qubits (for example, qubit 1, qubit 2, qubit 3, and qubit 4 as shown in FIG. 1), and a circuit structure for controlling and reading the qubits; and a transmission device 2, on which a ground layer 24 and at least one micro-strip line layer 22 are formed, wherein the quantum chip 1 is mounted on the transmission device 2 via Flip Chip or Wire Bond, the ground layer 24 and the quantum chip 1 are common-grounded, and a conductor strip 2231 in the micro-strip line layer 22 is coupled to the superconducting circuit. It should be understood that for the purpose of explanation, FIG. 1 only represents four qubits, qubit 1, qubit 2, qubit 3, and qubit 4 for example, which do not limit the embodiments of the present application.

A transmission device 2 provided by the embodiments of the present application will be further introduced below with reference to the accompanying drawings. The transmission device 2 includes:
a substrate 21, which is formed of a non-conductive material (for example, sapphire or high-resistance silicon);
a micro-strip line layer 22 formed on the substrate 21, wherein a structure of a micro-strip transmission line formed on the micro-strip line layer 22, for example, the micro-strip transmission line can be a symmetric micro-strip transmission line or an asymmetric micro-strip transmission line;
a dielectric layer 23 formed on the micro-strip line layer 22; and
a ground layer 24 and a port pad formed on the dielectric layer 23, wherein the ground layer 24 is electrically connected to the ground plate of the micro-strip line layer 22, and the port pad is electrically connected to a conductor strip 2231 of the micro-strip line layer 22.

It can be understood that a micro-strip transmission line is a microwave transmission line, which is composed of a ground plate, a dielectric and a conductor strip. The micro-strip line layer 22 with a micro-strip transmission line is formed on the substrate 21, and then the dielectric layer 23, as well as the ground layer 24 and the port pad are formed, which has the advantages of small size, light weight, and high degree of integration.

Compared with the transmission route on the PCB substrate in the prior art, in the transmission device 2 provided by the embodiment of the present application, the micro-strip line layer 22 is formed on the substrate 21, the dielectric layer 23 is formed on the micro-strip line layer 22, the ground layer 24 and the port pad are formed on the dielectric layer 23, the ground layer 24 is electrically connected to the ground plate of the micro-strip line layer 22, and the port pad is electrically connected to the conductor strip 2231 of the micro-strip line layer. In this way, the structure of the microwave transmission device 2 that can be fabricated based on the existing integrated circuit fabricating process can be obtained. Moreover, in this transmission device 2, the micro-strip line layer 22 can have a multi-layer stacking arrangement, so that high-density wiring on the substrate 21 with a limited area can be achieved to adapt to the packaging needs of large-scale quantum chips 1.

In some embodiments of the present application, the transmission device 2 includes multiple micro-strip line layers 22, and the multiple micro-strip line layers 22 are sequentially stacked on the substrate 21, each micro-strip line layer 22 is provided with a structure of micro-strip transmission line. In other embodiments of the present application, the micro-strip line layer 22 includes multiple conductor strips 2231, so that each micro-strip line layer 22 can be provided with a structure with multiple micro-strip line transmissions.

In some embodiments of the present application, the micro-strip line layer 22 is provided with a symmetrical micro-strip transmission line or an asymmetric micro-strip transmission line. The symmetrical micro-strip transmission line includes stacked two ground plates (for example, the two ground plates include a first ground plate 221 and a second ground plate 225), a dielectric between the two ground plates (for example, the dielectric includes a first dielectric layer 222 and a second dielectric layer 224), and a conductor strip 2231 located in the dielectric. The asymmetric micro-strip transmission line includes a ground plate, a dielectric located on the ground plate, and a conductor strip 2231 located on the dielectric. For example, there are only the first ground plate 221, the first dielectric layer 222, and the conductor strip 2231. That is, in one embodiment disclosed in the present application, the proposed transmission device 2 has a single ground plate for a given conductor strip 2231, and the conductor strip 2231 is separated from the first ground plate 221 through the first dielectric layer 222. This micro-strip transmission line can be referred to as “asymmetric micro-strip transmission line”. In another embodiment disclosed in the present application, the proposed transmission device 2 includes a substrate 21, a first ground plate 221 disposed on the substrate 21, a first dielectric layer 222 disposed on the first ground plate 221, a conductor strip 2231 disposed on the first dielectric layer 222, a second dielectric layer 224 disposed on the conductor strip 2231, and a second ground plate 225 disposed on the second dielectric layer 224. Therefore, in embodiments of the present disclosure, there are two ground planes for the given conductor strip 2231, and the conductor strip 2231 is separated from each ground plate by a respective dielectric (i.e., the conductor strip 223 is provided between the two ground planes or sandwiched between the two ground plates). Such micro-strip transmission line can be referred to as “symmetrical micro-strip transmission line”.

In one embodiment, a deposition hole is formed between the ground layer 24 and the ground plate. An electrical element is formed in the deposition hole. The electrical element is configured to realize an electrical connection between the ground layer and the ground plate to ensure that the ground layer 24 and the ground plate are at the same potential. As shown in FIG. 3 and FIG. 4, the electrical element includes a first electrical element 274 for electrically connecting the first ground plate 221 and the ground layer 24, and a second electrical element 273 for electrically connecting the second ground plate 225 and the ground layer 24. It can be understood that the deposition hole can be formed by etching or other methods. A deposition hole for forming the first electrical element 274 is formed on the surface of the ground layer 24. A portion of the surface of the first ground plate 221 is exposed through the deposition hole, so that the electrical connection between the ground layer 24 and the first ground plate 221 can be achieved when the deposition hole is plated or filled. Similarly, a deposition hole for forming the second electrical element 273 is formed on the surface of the ground layer 24. A portion of the surface of the second ground plate 225 is exposed through the deposition hole, so that the electrical connection between the ground layer 24 and the second ground plate 225 can be achieved when the deposition hole is plated or filled.

In one embodiment, the electrical element is a superconducting material plated on the inner wall of the deposition hole, or filled inside the deposition hole. The superconducting materials are superconducted within a critical temperature range. The superconducting material is aluminum (Al), niobium (Nb) or titanium nitride (TiN). Material forming the electrical element includes niobium nitride (NbN) and niobium titanium nitride (NbTiN), etc., all of which are specific types of superconductor. However, in other embodiments, other suitable superconductors may be used. The method for forming the electrical element includes any material deposition method, including but not limited to physical vapor deposition (PVD), chemical vapor deposition (CVD), plasma enhanced PVD, plasma enhanced CVD, and atomic layer deposition (ALD).

In another embodiment, the dielectric layer 23 is made of α-Si, silicon dioxide or silicon nitride. In some embodiments, the dielectric layer 23 is silicon dioxide and has a thickness of approximately 200 nanometers. In some embodiments, the thickness of the dielectric layer 23 using silicon dioxide is between approximately 150 nanometers and approximately 300 nanometers, which can be selected as needed during specific implementation. In some embodiments, the dielectric layer 23 is silicon nitride and has a thickness of approximately 100 nanometers. In some embodiments, the thickness of the dielectric layer 23 using silicon nitride is between approximately 10 nanometers and approximately 80 nanometers, which can be selected as needed during specific implementation.

In some embodiments, the silicon dioxide is deposited in such a manner that silicon dioxide is formed using a chemical vapor deposition (CVD) process based on Tetraethoxysilane (based on TEOS). TEOS is a process used to form silicon dioxide. In other implementations, the silicon dioxide is deposited using a high-density plasma (HDP) based on monosilane (SiH4) gas. In some embodiments where the dielectric layer 23 is silicon nitride, the dielectric layer 23 is added by physical vapor deposition (PVD). Thus, stages such as depositing an insulating layer or depositing an oxide, and variations (such as depositing silicon oxide), refer to depositing said material on another layer. This is different from using a chemical reaction with a layer or substrate to form or grow an insulating layer, such as exposing a silicon layer or substrate to oxygen or some other material to form or grow the oxide layer.

In one embodiment, the thickness of the ground plate, the conductor strip 2231 and the ground layer 24 is between 20 nm and 150 nm, and the specific thickness can be selected and implemented as need and the integrated circuit process.

In one embodiment, the port pad includes a first port 26 for electrically connected with the quantum chip 1, and a second port 25 for electrically connected with the controlling and reading apparatus, wherein a flux layer is formed on the first port 26 to facilitate soldering with the quantum chip 1 during the mounting process of Flip Chip or Wire Bond. The flux layer can be a formed gold film, titanium nitride film, etc. In the embodiment of the present application, the electrical connection between the port pad and the conductor strip 2231 of the micro-strip line layer 22 includes the electrical connection between one end of the conductor strip 2231 and the first port 26 and the electrical connection between the other end of the conductor strip 2231 and the second port 25. Specifically, a hole can be formed through the ground layer 24, the dielectric layer 23, the second ground plate 225 and the second dielectric layer 224, and the first superconducting element 271 and the second superconducting element 272 can be obtained by plating or depositing superconducting materials in the hole, so that the first superconducting element 271 is used to electrically connect one end of the conductor strip 2231 to the first port 26, and the second superconducting element 272 is used to electrically connect the other end of the conductor strip 2231 to the second port 25.

An embodiment of the present application further provides a quantum device integration component, which includes:
a quantum chip 1, on which a superconducting circuit is formed; and
the transmission device 2 described in the above embodiment of the present application, wherein the quantum chip is mounted on the transmission device 2 via Flip Chip or Wire Bond, the ground layer 24 and the quantum chip 1 are common-grounded, and the conductor strip 2231 and the superconducting circuit are coupled.

In one embodiment, the quantum chip 1 is provided with a through-hole. A superconducting interconnector 3 is formed in the through-hole, and the superconducting interconnector 3 and the port pad are connected in contact. Materials forming the superconducting interconnector 3 include aluminum (Al), niobium (Nb), niobium nitride (NbN), titanium nitride (TiN), and niobium titanium nitride (NbTiN), all of which are specific types of a superconductor. However, in other embodiments, other suitable superconductors may be used. The method for forming the superconducting interconnector 3 includes any material deposition method, including but not limited to physical vapor deposition (PVD), chemical vapor deposition (CVD), plasma enhanced PVD, plasma enhanced CVD, and atomic layer deposition (ALD).

The quantum device integration component provided by the embodiments of the present application includes the transmission device 2 and the quantum chip 1 mounted on the transmission device via Flip Chip or Wire Bond. While realizing high-density wiring, since the micro-strip transmission line formed on the transmission device 2 is separated from the quantum chip 1 by the ground layer 24, when the number of qubits is great, the signal on the micro-strip transmission line does not cause interference to other qubits operations. For example, due to the large number of qubits on the quantum chip, the conductor strip 2231 coupled with qubit 1 will inevitably pass directly under other qubits (for example, qubit 2, qubit 3, or qubit 4) when routing on the transmission device 2. Since in the embodiments of the present application, the conductor strip 2231 is separated from the quantum chip 1 by the ground layer 23, the signal transmission on the conductor strip 2231 will not cause interference to other qubits. For example, it will not cause false control of quantum states of other qubits.

Here, it should be noted that the transmission device 2 in the above quantum device integration component has similar structure to the above structure, and has the same beneficial effects as the embodiments of the above-mentioned transmission device 2, thereby no further details to be given. For technical details not disclosed in the embodiments of the quantum device integration component in the present application, those skilled in the art should refer to the descriptions of the embodiments of the above-mentioned transmission device 2 for understanding. In order to save space, they will not be described again here.

In a third aspect, an embodiment of the present application further provides a quantum computer, which is provided with at least the transmission device 2 described in the embodiments of the present application, or the quantum device integration component described in the embodiment of the present application.

Here, it should be noted that the transmission device 2 and the quantum device integration component in the above quantum computer are similar to those in the above description, and have the same beneficial effects as the embodiments of the above-mentioned transmission device 2 and the embodiments of the above-mentioned quantum device integration component, thereby no further details to be given. For technical details not disclosed in the embodiments of the quantum computer in the present, those skilled in the art should refer to the descriptions of the embodiments of the above-mentioned transmission device 2 and the embodiments of the above-mentioned quantum device integration component to understand. In order to save space, they will not be described again here.

In a fourth aspect, an embodiment of the present application further provides a method for fabricating a transmission device, including:
providing a substrate 21, which is formed of a non-conductive material (for example, sapphire);
forming a micro-strip line layer 22 on the substrate 21, wherein the micro-strip line layer 22 is provided with a structure of a micro-strip transmission line, for example, the micro-strip transmission line can be a symmetric micro-strip transmission line or an asymmetric micro-strip transmission line;
forming a dielectric layer 23 on the micro-strip line layer 22; and
forming a ground layer 24 and a port pad on the dielectric layer 23, wherein the ground layer 24 is electrically connected to a ground plate of the micro-strip line layer 22, and the port pad is electrically connected to a conductor strip of the micro-strip line layer 22.

In an embodiment of the present application, any one of dielectric can be deposited on the substrate 21 by using a CVD process. In one embodiment, the substrate 21 includes silicon and the first dielectric layer 23 includes silicon dioxide. In one embodiment, a semiconductor manufacturing apparatus planarizes the first dielectric layer 23. For example, the semiconductor manufacturing apparatus uses a CMP process to planarize the first dielectric layer 23.

In the transmission device 2 of one embodiment, the micro-strip line layer 22 is formed on the substrate 21, the dielectric layer 23 is formed on the micro-strip line layer 22, the ground layer 24 and the port pad are formed on the dielectric layer 23, the ground layer 24 is electrically connected to the ground plate of the micro-strip line layer 22, and the port pad is electrically connected to the conductor strip 2231 of the micro-strip line layer. In this way, the structure of the microwave transmission device 2 that can be fabricated based on the existing integrated circuit fabricating process can be obtained. Moreover, in this transmission device 2, the micro-strip line layer 22 can have a multi-layer stacking arrangement, so that high-density wiring on the substrate 21 with a limited area can be achieved to adapt to the packaging needs of large-scale quantum chips 1.

The above embodiments based on the schematic diagram provide a detailed explanation of the structure, features, and effects of the present application. The above descriptions are only preferred embodiments of the present application, but the present application does not limit the scope of implementation as shown on the drawings. Any changes made to the concept of the present application, or modifications to equivalent embodiments with equivalent changes, shall be within the protection scope of this application as long as they do not exceed the spirit covered by the description and drawings.

What is claimed is:

1. A transmission device, comprising:
a substrate;
a micro-strip line layer, formed on the substrate;
a dielectric layer, formed on the micro-strip line layer; and
a ground layer and a port pad, formed on the dielectric layer, wherein the ground layer is electrically connected to a ground plate of the micro-strip line layer, and the port pad is electrically connected to a conductor strip of the micro-strip line layer.

2. The transmission device according to claim 1, wherein the transmission device comprises multiple micro-strip line layers, and the multiple micro-strip line layers are stacked sequentially on the substrate.

3. The transmission device according to claim 1, wherein the micro-strip line layer comprises multiple conductor strips.

4. The transmission device according to claim 1, wherein the micro-strip line layer is provided with a symmetric micro-strip transmission line or an asymmetric micro-strip line.

5. The transmission device according to claim 1, wherein a deposition hole is formed between the ground layer and the ground plate, wherein an electrical element is formed in the deposition hole, and the electrical element is configured to achieve an electrical connection between the ground layer and the ground plate.

6. The transmission device according to claim 5, wherein the electrical element is a superconducting material plated on an inner wall of the deposition hole, or a superconducting material filled inside of the deposition hole.

7. The transmission device according to claim 6, wherein the superconducting material is Al, Nb, or TiN.

8. The transmission device according to claim 1, wherein the dielectric layer is made of α-Si, silicon dioxide, or silicon nitride.

9. The transmission device according to claim 1, wherein the thickness of each of the ground plate, the conductor strip and the ground layer is between 20 nm and 150 nm.

10. The transmission device according to claim 1, wherein the port pad comprises a first port configured to be electrically connected to the quantum chip, and a second port configured to be electrically connected to a controlling and reading apparatus, wherein a flux layer is formed on the first port.

11. A quantum device integration component, comprising:
a quantum chip, on which a superconducting circuit is formed; and
the transmission device according to claim 1, wherein the quantum chip is mounted on the transmission device via Flip Chip or Wire Bond, the ground layer and the quantum chip are common-grounded, and the conductor strip is coupled to the superconducting circuit.

12. The quantum device integration component according to claim 11, wherein a through-hole is formed on the quantum chip, a superconducting interconnector is formed in the through-hole, and the superconducting interconnector and the port pad are connected in contact.

13. A quantum computer, which is at least provided with the transmission device according to claim 1.

14. A method for fabricating a transmission device, comprising:
providing a substrate;
forming a micro-strip line layer on the substrate;
forming a dielectric layer on the micro-strip line layer; and
forming a ground layer and a port pad on the dielectric layer, wherein the ground layer is electrically connected to a ground plate of the micro-strip line layer, and the port pad is electrically connected to a conductor strip of the micro-strip line layer.

15. The transmission device according to claim 2, wherein the micro-strip line layer is provided with a symmetric micro-strip transmission line or an asymmetric micro-strip line.

16. A quantum device integration component, comprising:
a quantum chip, on which a superconducting circuit is formed; and
the transmission device according to claim 2, wherein the quantum chip is mounted on the transmission device via Flip Chip or Wire Bond, the ground layer and the quantum chip are common-grounded, and the conductor strip is coupled to the superconducting circuit.

17. A quantum device integration component, comprising:
a quantum chip, on which a superconducting circuit is formed; and
the transmission device according to claim 3, wherein the quantum chip is mounted on the transmission device via Flip Chip or Wire Bond, the ground layer and the quantum chip are common-grounded, and the conductor strip is coupled to the superconducting circuit.

18. A quantum device integration component, comprising:
a quantum chip, on which a superconducting circuit is formed; and
the transmission device according to claim 4, wherein the quantum chip is mounted on the transmission device via Flip Chip or Wire Bond, the ground layer and the quantum chip are common-grounded, and the conductor strip is coupled to the superconducting circuit.

19. A quantum device integration component, comprising:
a quantum chip, on which a superconducting circuit is formed; and
the transmission device according to claim 5, wherein the quantum chip is mounted on the transmission device via Flip Chip or Wire Bond, the ground layer and the quantum chip are common-grounded, and the conductor strip is coupled to the superconducting circuit.

20. A quantum computer, which is at least provided with the quantum device integration component according to claim 11.
